(19) United States
(12) Patent Application Publication
(10) Pub. No.: US 2025/0096152 A1
(43) Pub. Date: Mar. 20, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Rho Gyu KWAK, Gyeonggi-do (KR); In Su PARK, Gyeonggi-do (KR); Jung Shik JANG, Gyeonggi-do (KR); Seok Min CHOI, Gyeonggi-do (KR); Won Geun CHOI, Gyeonggi-do (KR)

(21) Appl. No.: 18/393,132

(22) Filed: Dec. 21, 2023

(30) Foreign Application Priority Data
Sep. 20, 2023 (KR) 10-2023-0125362

(51) Int. Cl. H01L 23/00; H01L 25/00; H01L 25/065; H01L 25/18; H10B 41/27; H10B 43/27; H10B 80/00

(52) U.S. Cl. CPC H01L 23/562; H01L 24/08; H01L 24/80; H01L 25/0657; H01L 25/18; H01L 25/50; H10B 41/27; H10B 43/27; H10B 80/00; H01L 2224/08145; H01L 2224/80895; H01L 2224/80896; H01L 2924/1431; H01L 2924/14511; H01L 2924/3511

(57) ABSTRACT

A semiconductor device may include a source structure, a support structure positioned on the source structure and including a first inclined surface extending in a second direction crossing the first direction, a gate structure positioned on the source structure and the support structure and including conductive layers and insulating layers alternately stacked, channel structures extending through the gate structure and connected to the source structure, and a slit structure extending in the first direction through the gate structure, wherein each of the conductive layers includes a second inclined surface extending in the second direction.

### CROSS-REFERENCE TO RELATED APPLICATION

This application claims priority under 35 U.S.C. § 119 to Korean Patent Application No. 10-2023-0125362 filed on Sep. 20, 2023, which is incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked over a substrate is being proposed. In addition, various structures and manufacturing methods are being developed to improve operation reliability of the semiconductor device.

### SUMMARY

According to an embodiment of the present disclosure, a semiconductor device may include a source structure, a support structure disposed over the source structure and the support structure including a first inclined surface extending in a second direction crossing the first direction, a gate structure disposed over the source structure and the support structure and the gate structure including conductive layers and insulating layers alternately stacked, channel structures extending through the gate structure and connected to the source structure, and a slit structure extending in the first direction through the gate structure, wherein each of the conductive layers includes a second inclined surface extending in the second direction.

According to an embodiment of the present disclosure, a semiconductor device may include a support structure including a first inclined surface, a gate structure including insulating layers and conductive layers alternately stacked on the support structure, each of the conductive layers including a second inclined surface, a channel structure extending through the second inclined surface of the gate structure, and a slit structure extending in a direction crossing the second inclined surface in the gate structure.

According to an embodiment of the present disclosure, a method of manufacturing a semiconductor device may include forming a source structure, forming a support structure on the source structure including a first inclined surface extending in a second direction crossing a first direction, forming a stack including first material layers and second material layers alternately stacked, on the source structure and the support structure, each of the second material layers including a second inclined surface, forming channel structures extending into the source structure through the stack, forming a slit extending in the first direction through the stack, and forming a slit structure in the slit.

According to an embodiment of the present disclosure, a method of manufacturing a semiconductor device may include forming a support structure including a first inclined surface, forming a stack including first material layers and second material layers alternately stacked, on the support structure, each of the second material layers including a second inclined surface, forming channel structures extending through the stack, and forming a slit structure extending in a direction crossing the second inclined surface in the stack.

These and other features and advantages of the present disclosure will become apparent from the following drawings and detailed description of example embodiments.

### BRIEF DESCRIPTION OF THE DRAWINGS

FIGS. 1A to 1C are diagrams illustrating a semiconductor device according to an embodiment of the present disclosure.

FIGS. 2A to 2C are diagrams illustrating a semiconductor device according to an embodiment of the present disclosure.

FIG. 3 is a diagram illustrating a semiconductor device according to an embodiment of the present disclosure.

FIGS. 4A to 4C are diagrams illustrating a method of manufacturing a semiconductor device according to an embodiment of the present disclosure.

FIGS. 5A to 6B are diagrams illustrating a method of manufacturing a semiconductor device according to an embodiment of the present disclosure.

FIGS. 7A and 7B are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and improved characteristics.

According to the present technology, a semiconductor device having a stable structure and improved characteristics may be provided. Hereinafter, embodiments according to the technical spirit of the present disclosure are described with reference to the accompanying drawings.

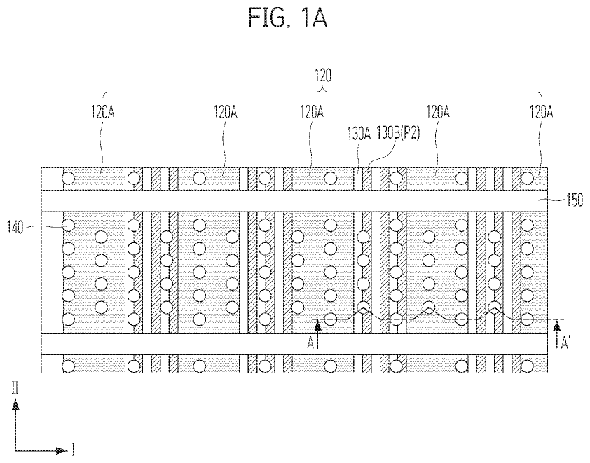

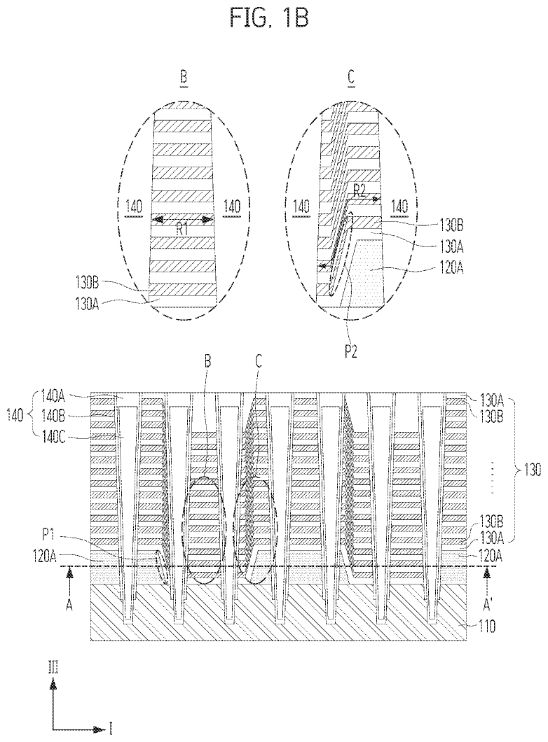

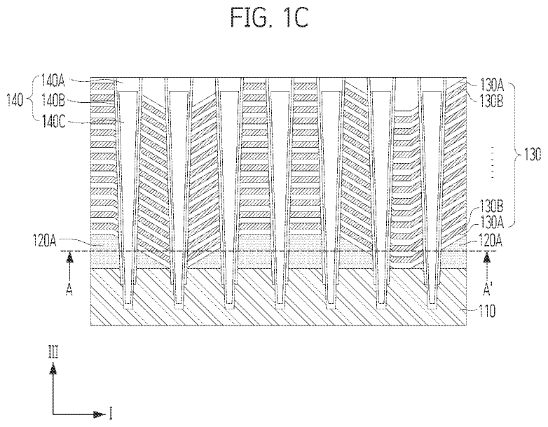

FIGS. 1A to 1C are diagrams illustrating a semiconductor device according to an embodiment of the present disclosure. FIG. 1A may be a plan view, and FIGS. 1B and 1C may be cross-sectional views taken along a line A-A′ of FIG. 1A.

Referring to FIGS. 1A to 1C, the semiconductor device may include at least one of a source structure 110, a support structure 120, a gate structure 130, channel structures 140, and a slit structure 150.

The support structure 120 may be positioned on the source structure 110. The support structure 120 may include a plurality of supports 120A. The supports 120A may be spaced apart in a first direction I at a regular interval. The supports 120A may be adjacent to each other in a second direction II crossing the first direction I. In an embodiment, the support structure 120 may have an overall curved shape profile with a plurality of alternating convex and concave portions. The convex portions may also be referred to as convex protrusions. The concave portions may also be referred to as concave valleys. In another embodiment the support structure may have an overall multi-angled profile comprising a plurality of alternating trapezoidal shape protrusions and valleys. The support structure 120 may include a first inclined surface P1 extending in the second direction II. For example, each of the supports 120A may include at least one first inclined surface P1. Each of the supports 120A may include a plurality of first inclined surfaces P1. Each support 120A may have an overall curved shape including a plurality of alternating convex and concave portions. The convex portions may also be referred to as convex protrusions. The concave portions may also be referred to as concave valleys. Each of the first inclined surface P1 may include a curved surface or an angled surface. The curved surface may be a convex surface, a concave surface, or a combination thereof. The support structure 120 may be used to reduce warpage of the semiconductor device in a third direction III crossing the first direction I and the second direction II. For example, the support structure 120 may serve to reduce bending of the semiconductor device due to a tensile stress or a compressive stress. The support structure 120 may include a material having an etch selectivity with respect to nitride. The support structure 120 may include an insulating material. For example, the support structure 120 may include an oxide or the like.

The gate structure 130 may be positioned on the source structure 110 and the support structure 120. The gate structure 130 may include insulating layers 130A and conductive layers 130B alternately stacked. For example, the gate structure 130 may include the insulating layers 130A and the conductive layers 130B alternately stacked according to a profile of the support structure 120 and the source structure 110 exposed between the supports 120A of the support structure 120. In a cross-section defined in the first direction I and the third direction III, each of the conductive layers 130B may include at least one second inclined surface P2. For example, each of the conductive layers 130B may have a wave-like shape in a cross-section. The second inclined surface P2 may be transferred from the first inclined surface P1 of the support structure 120. As a result, each conductive layer 130B may have an overall multi-angled profile including a plurality of alternating trapezoidal shape protrusions and valleys. For example, the second inclined surface P2 may extend in the second direction II and may include a curved surface or an angled surface. Here, the conductive layers 130B may be used as a word line, a bit line, or a selection line. In addition, the conductive layers 130B may include a conductive material such as tungsten, molybdenum, or polysilicon.

For reference, a shape of the second inclined surfaces P2 of the conductive layers 130 may be different for each level of the conductive layers 130. For example, the second inclined surfaces P2 of the conductive layers 130 relatively adjacent to the support structure 120 may have a shape transferred from the first inclined surface P1 of the support structure 120, and the second inclined surfaces P2 of the conductive layers 130 relatively spaced apart from the support structure 120 might not have a shape transferred from the first inclined surface P1 of the support structure 120.

When the first inclined surface P1 of the support structure 120 has a curved surface or an angled surface, the second inclined surfaces P2 of the conductive layers 130 relatively adjacent to the support structure 120 may have a curved surface or an angled surface obtained by transferring the shape of the first inclined surface P1. On the other hand, the second inclined surfaces P2 of the conductive layers 130 relatively spaced apart from the support structure 120 may have a relatively widely spread shape of curved surface rather than having a shape obtained by transferring the shape of the first inclined surface P1. This may be determined according to a characteristic of a conductive material configuring the conductive layers 130 or a method of manufacturing the conductive layers 130.

As the gate structure 130 increases in the third direction III, tensile stress or compressive stress may occur from structures included in the semiconductor device, and warpage may occur. In a cross-section, when the conductive layers 130B have a wave-like shape including the second inclined surface P2, the warpage of the semiconductor device may be reduced by dispersing stress due to the gate structure 130. For example, referring to a portion C of FIG. 1B, when the conductive layers 130B have the wave-like shape, stress of the gate structure 130 may be dispersed through the second inclined surface P2. Therefore, the warpage of the semiconductor device may be reduced.

The channel structures 140 may pass through the gate structure 130. For example, the channel structures 140 may pass through the gate structure 130 and may be connected to the source structure 110. Each of the channel structures 140 may include at least one of a channel layer 140A, a memory layer 140B surrounding the channel layer 140A, and an insulating core 140C in the channel layer 140A. Here, the channel layer 140A may be connected to the source structure 110.

At least one of the channel structures 140 may pass through the second inclined surface P2 of the conductive layers 130B. For example, referring to FIG. 1B, one channel structure 140 may pass through one second inclined surface P2. As another example, referring to FIG. 1C, a plurality of channel structures 140 may pass through one second inclined surface P2. At least one channel structure 140 may pass through one second inclined surface P2. Each of the conductive layers 130B may have a wave-like shape in a cross-section and may have the second inclined surface P2 between the channel structures 140. In a case of the conductive layers 130B including the second inclined surface P2, a length of the conductive layers 130B between the channel structures 140 may be increased. Referring to a portion B of FIG. 1B, the conductive layers 130B may have a first length R1, and referring to a portion C, the conductive layers 130B may have a second length R2 larger than the first length R1. When the conductive layers 130B have the relatively long second length R2, the semiconductor device may reduce interference between the channel structures 140 adjacent in the first direction I. Therefore, according to an embodiment of the present disclosure, interference between memory cells adjacent in the first direction I may be reduced.

Referring to FIG. 1A, the slit structure 150 may extend in the first direction I through the gate structure 130. The supports 120A may be adjacent in the second direction II, and the slit structure 150 may be positioned between the supports 120A adjacent in the second direction II. The second inclined surface P2 of the conductive layers 130B and the slit structure 150 may cross. For example, the slit structure 150 may extend in the first direction I, and an inclined surface P may extend in the second direction II crossing the first direction I.

The slit structure 150 may extend in the first direction I, and the gate structure 130 may be patterned in the first direction I by the slit structure 150. For example, the conductive layers 130B may be patterned in the first direction I. Because the conductive layers 130B are patterned only in the first direction I, warpage may occur. According to one embodiment of the present disclosure, warpage may be reduced because the conductive layers 130B have the wave-like shape in a cross-section. The slit structure 150 may include at least one of an insulating material, a conductive material, and a semiconductor material.

According to the structure described above, the conductive layers 130B may have the wave-like shape in the cross-section defined in the first direction I and the third direction III. Therefore, the warpage of the semiconductor device may be reduced.

The conductive layers 130B may have the relatively long second length R2 between the channel structures 140. Therefore, interference between memory cells adjacent in the first direction I may be reduced.

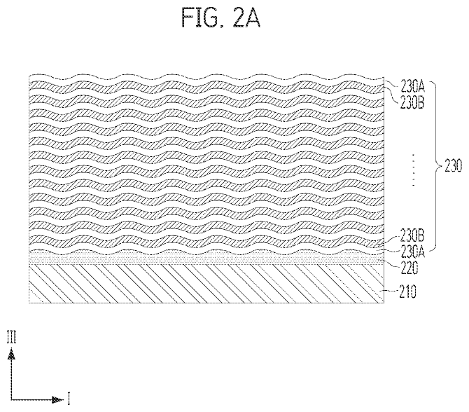

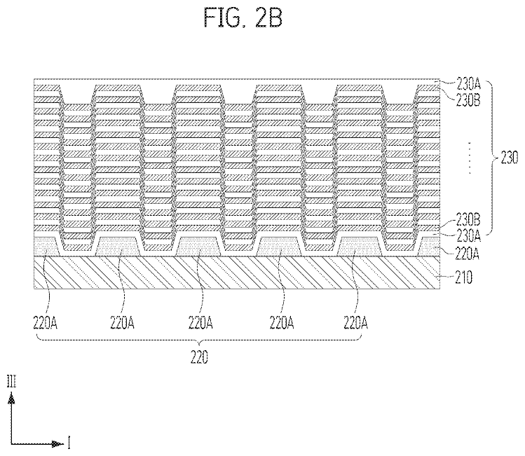

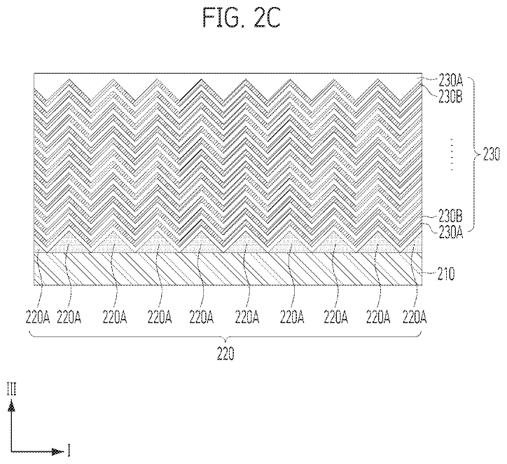

FIGS. 2A to 2C are diagrams illustrating a semiconductor device according to an embodiment of the present disclosure. Hereinafter, a content that overlaps the content described above may be omitted.

Referring to FIGS. 2A to 2C, a support structure 220 may be positioned on a source structure 210. Referring to FIG. 2A, the support structure 220 may include at least one curved surface including a plurality of alternating convex protrusions and concave valleys. For example, the support structure 220 may have a wave-like shape. A gate structure 230 may be positioned on the support structure 220.

The gate structure 230 may include insulating layers 230A and conductive layers 230B alternately stacked, and may be positioned according to the wave profile of the support structure 220. Therefore, each of the conductive layers 230B may also have a wave-like shape profile including a plurality of alternating convex protrusions and concave valleys.

Referring to FIG. 2B, the support structure 220 may include a plurality of supports 220A each support having a profile of a trapezoidal shape protrusion. Here, the supports 220A may be spaced apart in the first direction I alternating with trapezoidal shape valleys. The source structure 210 may be exposed between the supports 220A. Each of the supports 220A may include at least one angled surface. For example, the support 220A may have a trapezoidal shape in the cross-section defined by the first direction I and the third direction III. However, the support 220A is not limited thereto and may have a shape of a circle, an ellipse, a polygon, or the like. The gate structure 230 may be positioned on the source structure 210 and the support structure 220. The gate structure 230 may include the insulating layers 230A and the conductive layers 230B alternately stacked on the source structure 210 and the support structure 220.

Referring to FIG. 2C, the support structure 220 may include the supports 220A. Each of the supports 220A may include at least one angled surface. For example, the support 220A may have a triangular shape in the cross-section. Here, the supports 220A may be connected in the first direction I. However, the supports 220A are not limited thereto, and the supports 220A may be spaced apart from each other in the first direction I. For example, the source structure 210 may be exposed between the supports 220A having the triangular shape. The gate structure 230 may be positioned on the support structure 220.

For reference, although not shown in the present drawing, the semiconductor device may further include channel structures. For example, the channel structures may extend into the source structure 210 through gate structure 230. However, for convenience of description, the channel structures are omitted.

According to the structure described above, the support structure 220 may include various shapes including at least one curved surface or angled surface. The support structure 220 may include the supports 220A, and the supports 220A may be connected or spaced apart from each other. During a manufacturing process, a profile of the support structure 220 may be transferred to the gate structure 230. Therefore, the gate structure 230 may include a curved surface or an angled surface.

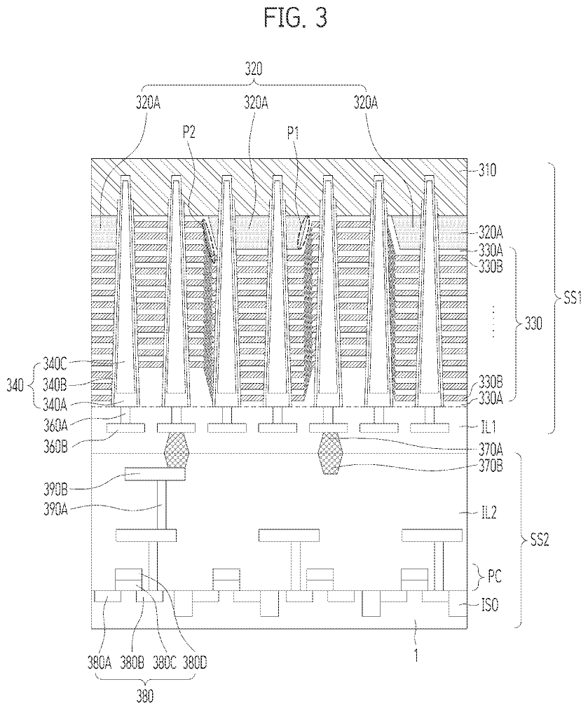

FIG. 3 is a diagram illustrating a semiconductor device according to an embodiment of the present disclosure. Hereinafter, a content that overlaps the content described above may be omitted.

Referring to FIG. 3, the semiconductor device may include at least one of a first semiconductor structure SS1 and a second semiconductor structure SS2. The first semiconductor structure SS1 may include at least one of a source structure 310, a support structure 320, a gate structure 330, channel structures 340, and a slit structure The first semiconductor structure SS1 may further include at least one of a first interlayer insulating layer IL1, first contact vias 360A, first lines 360B, and first bonding pads 370A.

The gate structure 330 may include insulating layers 330A and conductive layers 330B alternately stacked. Each of the conductive layers 330B may include at least one second inclined surface P2 in the cross-section defined in the first direction I and the third direction III. For example, each of the conductive layers 330B may have a wave-like shape in the cross-section. Here, the second inclined surface P2 may extend in the second direction II crossing the first direction I and the third direction III. As the conductive layers 330B have the wave-like shape in the cross-section, the stress due to the gate structure 330 may be distributed, thereby reducing the warpage of the semiconductor device. The conductive layers 330B may be used as a word line, a bit line, a selection line, or the like. The conductive layers 330B may include a conductive material such as tungsten, molybdenum, or polysilicon.

The support structure 320 may be positioned on the gate structure 330. The support structure 320 may include supports 320A, and the supports 320A may be spaced apart in the first direction I. The support structure 320 may include at least one first inclined surface P1. Here, the first inclined surface P1 may extend in the second direction II. The support structure 320 may include a material having an etch selectivity with respect to nitride. The support structure 320 may include an insulating material such as oxide.

The channel structures 340 may pass through gate structure 330 and may be connected to the source structure 310. Here, the source structure 310 may be positioned on the gate structure 330 and the support structure 320. At least one of the channel structures 340 may pass through the second inclined surface P2 of the conductive layers 330B. Each of the channel structures 340 may include at least one of a channel layer 340A, a memory layer 340B, and an insulating core 340C. Here, the channel layer 340A may be connected to the source structure 310.

At least one of the first contact vias 360A, the first lines 360B, and the first bonding pads 370A may be positioned under the gate structure 330. The first contact vias 360A, the first lines 360B, and the first bonding pads 370A may be positioned in the first interlayer insulating layer IL1. Here, the first interlayer insulating layer IL1 may be positioned under the gate structure 330. The first contact vias 360A may be respectively connected to the channel structures 340. The first lines 360B may be respectively connected to the first contact vias 360A. Each of the first bonding pads 370A may be connected to at least one of the first lines 360B. The first contact vias 360A, the first lines 360B, and the first bonding pads 370A may include a conductive material such as aluminum, copper, or tungsten.

The second semiconductor structure SS2 may be positioned under the first semiconductor structure SS1. The first semiconductor structure SS1 and the second semiconductor structure SS2 may be bonded. For example, the first semiconductor structure SS1 may be reversed and an upper portion of the first semiconductor structure SS1 and an upper portion of the second semiconductor structure SS2 may be bonded. The second semiconductor structure SS2 may include a peripheral circuit PC. The second semiconductor structure SS2 may further include at least one of a substrate 1, an isolation insulating layer ISO, a transistor 380, a second contact via 390A, second lines 390B, and second bonding pads 370B.

The peripheral circuit PC may be positioned on the substrate 1, and the isolation insulating layer ISO may be positioned in the substrate 1. An active region may be defined by the isolation insulating layer ISO. The peripheral circuit PC may include the transistor 380, a capacitor, a resistor, and the like. For example, the transistor 380 may include a first junction 380A, a second junction 380B, a gate insulating layer 380C, and a gate electrode 380D. The gate insulating layer 380C may be positioned between the gate electrode 380D and the substrate 1. The gate insulating layer 380C and the isolation insulating layer ISO may include an insulating material such as oxide or nitride.

At least one of the second contact vias 390A, the second lines 390B, and the second bonding pads 370B may be included on the substrate 1. The second contact vias 390A, the second lines 390B, and the second bonding pads 370B may be positioned in a second interlayer insulating layer IL2. Here, the second interlayer insulating layer IL2 may be positioned on the substrate 1. At least one of the second contact vias 390A may be connected to the transistor 380. The second lines 390B may be respectively connected to the second contact vias 390A. Each of the second bonding pads 370B may be connected to at least one of the second lines 390B. The second contact vias 390A, the second lines 390B, and the second bonding pads 370B may include a conductive material such as aluminum, copper, or tungsten.

According to the structure described above, the first semiconductor structure SS1 may be configured around a memory cell array including the channel structures 340 and the like, and the second semiconductor structure SS2 may be configured around the peripheral circuit PC related to an operation of the memory cell array. Therefore, by configuring the peripheral circuit PC related to the operation of the memory cell array to be included in the separate second semiconductor structure SS2, more memory cells may be positioned in the first semiconductor structure SS1, and thus more data may be stored.

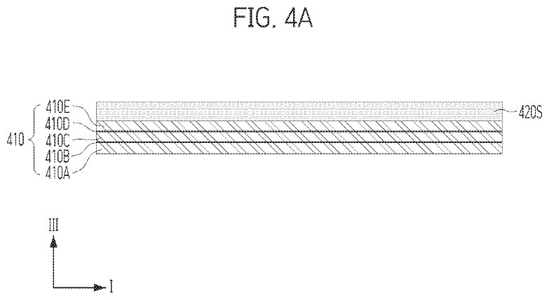

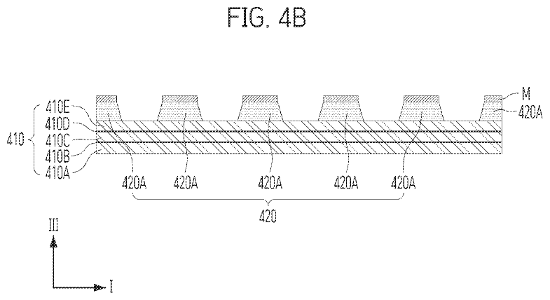

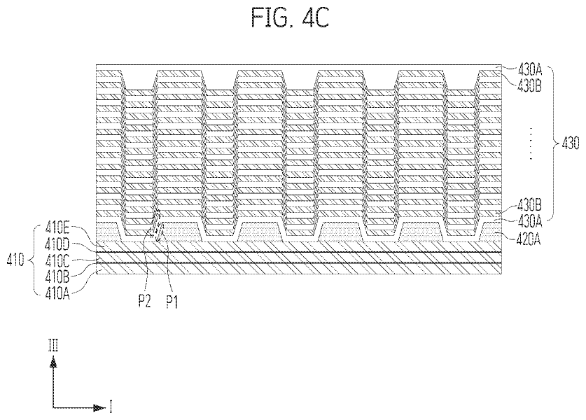

FIGS. 4A to 4C are diagrams illustrating a method of manufacturing a semiconductor device according to an embodiment of the present disclosure. Hereinafter, a content that overlaps the content described above may be omitted.

Referring to FIG. 4A, a source structure 410 may be formed. The source structure 410 may be formed by sequentially forming a first source layer 410A, a first protective layer 410B, a source sacrificial layer 410C, a second protective layer 410D, and a second source layer 410E. Subsequently, a preliminary support structure 420S may be formed on the source structure 410. Here, the preliminary support structure 420S may include an insulating material such as oxide.

Referring to FIG. 4B, a mask pattern M may be formed on the preliminary support structure 420S. Subsequently, a support structure 420 may be formed by patterning the preliminary support structure 420S using the mask pattern M as an etch barrier. According to a shape of the mask pattern M, a shape of the support structure 420 may be different. For example, in a process of patterning the preliminary support structure 420S, a portion of the mask pattern M may be etched and removed. In this case, the support structure 420 may include at least one first inclined surface P1. In addition, the support structure 420 may have different shapes of inclined surfaces according to an etching process condition.

The first inclined surface P1 may include a curved surface or an angled surface. For example, the support structure 420 may have a trapezoidal shape, a triangular shape, or the like in the cross-section defined by the first direction I and the third direction III. Alternatively, the support structure 420 may have a wave-like shape in the cross-section. Therefore, the first inclined surface P1 may include a curved surface or an angled surface. However, the support structure 420 is not limited thereto, and the support structure 420 may have a shape of a polygon, a circle, an ellipse, or the like.

In a process of forming the support structure 420, the preliminary support structure 420S may be patterned so that the source structure 410 is exposed. In this case, the support structure 420 may be separated in the first direction I. Therefore, the support structure 420 may include supports 420A spaced apart in the first direction I. However, the present disclosure is not limited thereto, and the preliminary support structure 420S may be patterned while maintaining an unseparated state.

Referring to FIG. 4C, a stack 430 may be formed by alternately stacking first material layers 430A and second material layers 430B on the source structure 410 and the support structure 420. For example, the stack 430 may be formed according to a profile of the source structure 410 and the support structure 420. Therefore, the profile of the support structure 420 may be transferred to the stack 430, and the stack 430 may include a curved surface or an angled surface. Each of the second material layers 430B may include at least one second inclined surface P2 in the cross-section. Each of the second material layers 430B may include a plurality of second inclined surfaces P2 in the cross-section. For example, each of the second inclined surfaces P2 may include a curved surface or an angled surface. The first material layers 430A may include an insulating material such as oxide, and the second material layers 430B may include a sacrificial material such as nitride. The support structure 420 may include a material having an etch selectivity with respect to the second material layers 430B.

For reference, a shape of the second inclined surfaces P2 of the second material layers 430 of the stack 430 may be different for each level. For example, the second material layers 430B formed relatively earlier on the support structure 420 may have a shape transferred from the first inclined surface P1 of the support structure 420, and the second material layers 430B formed relatively later might not have the shape transferred from the first inclined surface P1.

When the first inclined surface P1 of the support structure 120 has a curved surface or an angled surface, the second inclined surfaces P2 of the second material layers 430B formed relatively earlier may have a curved surface or an angled surface obtained by transferring a shape of the first inclined surface P1, and the second inclined surfaces P2 of the second material layers 430B formed relatively later may have a relatively widely spread shape of curved surface rather than having a shape obtained by transferring the shape of the first inclined surface P1. This may be determined according to a characteristic of a material configuring the second material layers 430B or a method of manufacturing the second materials 430B.

According to the manufacturing method described above, the stack 430 may be formed according to the profile of the support structure 420. The second material layers 430B of the stack 430 may include the second inclined surface P2 transferred from the first inclined surface P1 of the support structure 420. The second inclined surface P2 may include a curved surface or an angled surface.

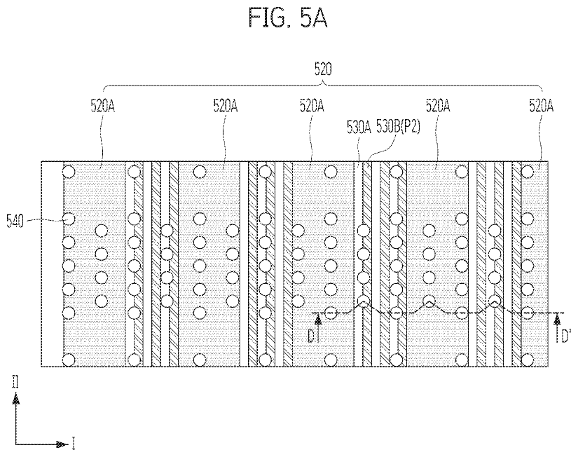

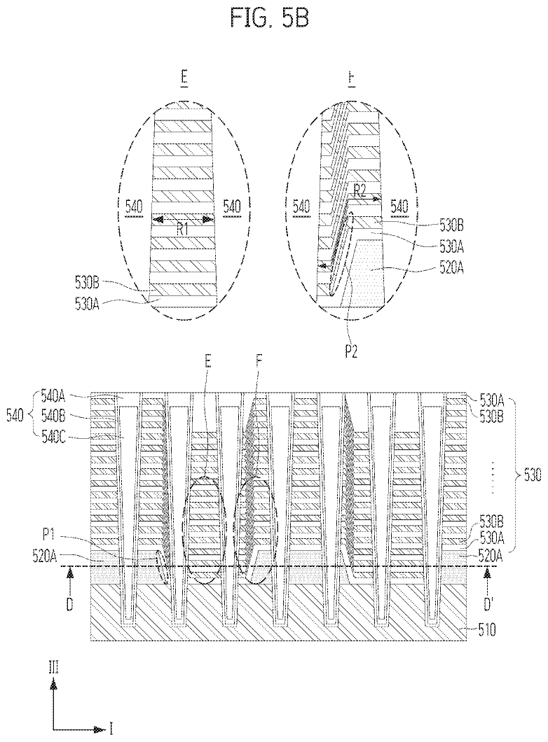

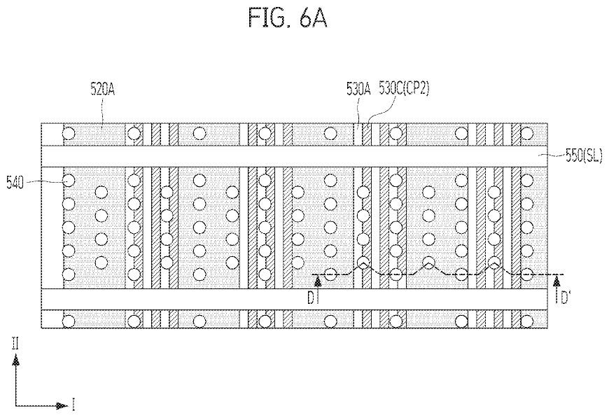

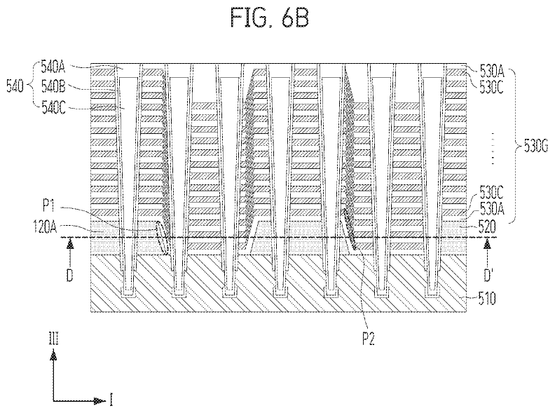

FIGS. 5A to 6B are diagrams illustrating a method of manufacturing a semiconductor device according to an embodiment of the present disclosure. FIGS. 5A and 6A may be plan views, and FIGS. 5B and 6B may be cross-sectional views taken along a line D-D′ of each plan view. Hereinafter, a content that overlaps the content described above may be omitted.

Referring to FIGS. 5A and 5B, a source structure 510 may be formed. Here, the source structure 510 may include at least one of a first source layer, a first protective layer, a source sacrificial layer, a second protective layer, and a second source layer. Subsequently, a support structure 520 may be formed on the source structure 510. First, a preliminary support structure (not shown) may be formed on the source structure 510. Subsequently, a mask pattern (not shown) may be formed on the preliminary support structure. Subsequently, the support structure 520 may be formed by patterning the preliminary support structure using the mask pattern as an etch barrier. The support structure 520 may include the first inclined surface P1 extending in the second direction II crossing the first direction I.

Subsequently, a stack 530 may be formed by alternately stacking first material layers 530A and second material layers 530B on the source structure 510 and the support structure 520. Each of the second material layers 530B may include at least one second inclined surface P2. Here, the second inclined surface P2 may be obtained by transferring the first inclined surface P1. This is because the stack 530 is formed according to the profile of the support structure 520.

Subsequently, channel structures 540 extending into the source structure 510 through the stack 530 may be formed. At least one of the channel structures 540 may pass through the second inclined surface P2 of the second material layers 530B. Each of the channel structures 540 may include at least one of a channel layer 540A, a memory layer 540B, and an insulating core 540C.

Referring to FIGS. 6A and 6B, a slit SL extending in the first direction I through the stack 530 may be formed. The stack 530 may be patterned in the first direction I by the slit SL. For example, the second material layers 530B may be patterned in the first direction I. Because the stack 530 is patterned only in the first direction I, warpage may occur. In addition, as the stack 530 increases in the third direction III, tensile stress or compressive stress may be induced from structures included in the semiconductor device, and warpage may occur. According to an embodiment of the present disclosure, because the second material layers 530B have a wave-like shape in the cross-section, the warpage may be reduced by dispersing stress due to the stack 530.

Subsequently, the second material layers 530B may be replaced with third material layers 530C through the slit SL. The third material layers 530C may include at least one second inclined surface P2. Accordingly, a gate structure 530G including the first material layers 530A and the third material layers 530C alternately stacked may be formed. Here, the third material layers 530C may include a conductive material such as tungsten, molybdenum, or polysilicon. For reference, when the second material layers 530B include a conductive material, the replacement process may be omitted.

At least one of the channel structures 540 may pass through the second inclined surface P2 of the third material layers 530C. Because the third material layers 530C have a wave-like shape, a length of the third material layers 530C between the channel structures 540 may be increased. When the length of the third material layers 530C between the channel structures 540 is increased, interference between the channel structures 540 may be reduced. Therefore, according to an embodiment of the present disclosure, interference between memory cells adjacent in the first direction I may be reduced.

Subsequently, a slit structure 550 may be formed in the slit SL. Here, the slit structure 550 may include at least one of an insulating material, a conductive material, and a semiconductor material. Before forming the slit structure 550, the source structure 510 and the channel structures 540 may be connected. For example, an opening may be formed by removing the source sacrificial layer of the source structure 510 through the slit SL, and a portion of the memory layer 540B of the channel structures 540 may be etched through the opening to expose the channel layer 540A. Subsequently, a semiconductor material may be formed in the opening to connect the source structure 510 and the channel layer 540A.

According to the manufacturing method described above, the second material layers 530B may have a wave-like shape in the cross-section defined by the first direction I and the third direction III. Therefore, the warpage of the semiconductor device may be reduced.

Because the third material layers 530C have a wave-like shape, the third material layers 530C may have a relatively long length between the channel structures 540. Therefore, interference between memory cells adjacent in the first direction I may be reduced.

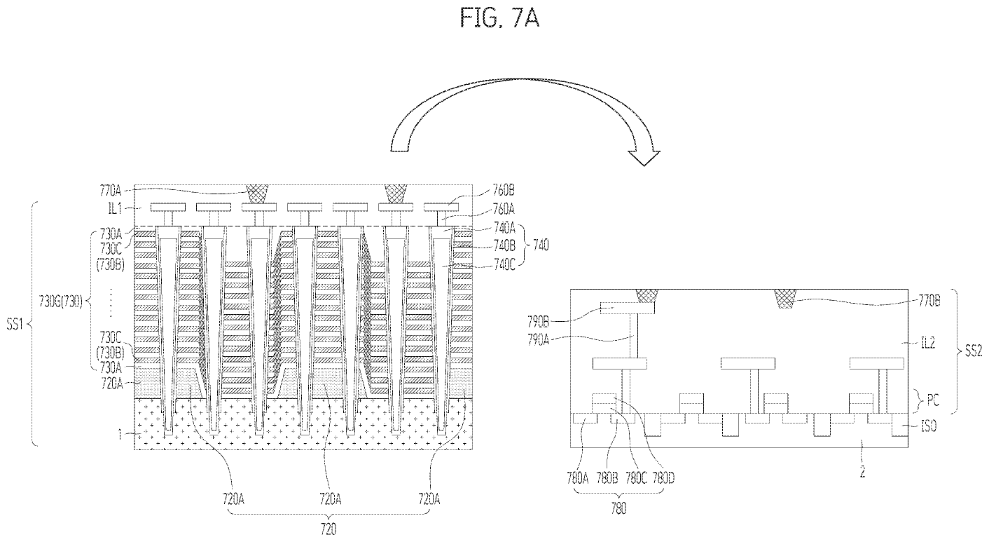

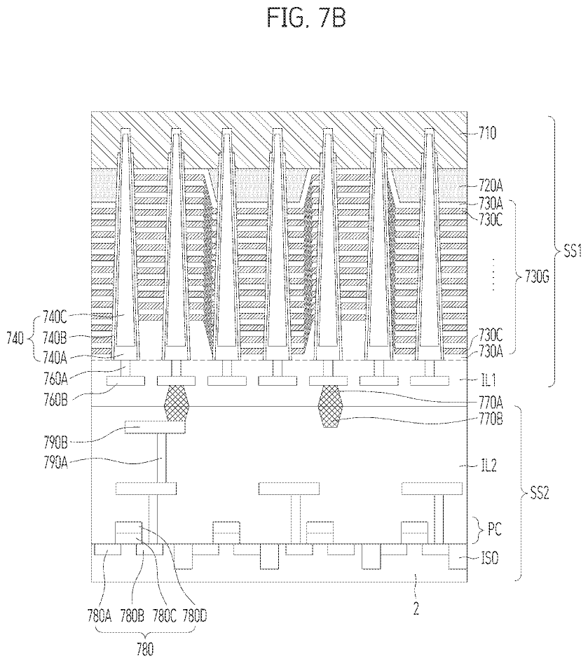

FIGS. 7A and 7B are diagrams illustrating a method of manufacturing a semiconductor device according to an embodiment of the present disclosure. Hereinafter, a content that overlaps the content described above may be omitted.

Referring to FIG. 7A, the first semiconductor structure SS1 may be formed. First, a support structure 720 including the first inclined surface P1 may be formed on the substrate 1. The support structure 720 may be formed by patterning a preliminary support structure (not shown). The support structure 720 may include trapezoidal shape supports 720A spaced apart from each other. Subsequently, a stack 730 may be formed by alternately stacking first material layers 730A and second material layers 730B on the support structure 720. Here, the second material layers 730B may have a second inclined surface P2.

Subsequently, channel structures 740 extending into the substrate 1 through the stack 730 may be formed. Each of the channel structures 740 may include at least one of a channel layer 740A, a memory layer 740B, and an insulating core 740C. Subsequently, a slit (not shown) extending in a direction crossing the second inclined surface P2 in the stack 730 may be formed. Subsequently, the second material layers 730B may be replaced with third material layers 730C through the slit. Accordingly, a gate structure 730G including the first material layers 730A and the third material layers 730C alternately stacked may be formed. Here, the third material layers 730C may be a word line, a bit line, or a selection line. Subsequently, a slit structure may be formed in the slit. However, the present disclosure is not limited thereto, and the stack 730 may be formed by alternately stacking the first material layers 730A and the third material layers 730C from the beginning. Here, the third material layers 730C may be silicided through the slit.

Subsequently, first contact vias 760A and first lines 760B may be formed on the gate structure 730G. Each of the first contact vias 760A may be connected to the channel structures 740. The first lines 760B may be respectively connected to the first contact vias 760A. Subsequently, first bonding pads 770A may be formed. The first bonding pads 770A may be connected to at least one of the first lines 760B. The first contact vias 760A, the first lines 760B, and the first bonding pads 770A may be formed in the first interlayer insulating layer IL1.

The second semiconductor structure SS2 may be formed. First, the peripheral circuit PC may be formed. The peripheral circuit PC may be formed on a substrate 2. The peripheral circuit PC may include a transistor 780. The transistor 780 may include at least one of junctions 780A and 780B, a gate insulating layer 780C, and a gate electrode 780D. The isolation insulating layer ISO may be formed in the substrate 2, and an active region of the transistor 780 may be defined by the isolation insulating layer ISO. Subsequently, second contact vias 790A and second lines 790B may be formed on the peripheral circuit PC. At least one of the second contact vias 790A may be connected to the transistor 780. The second lines 790B may be respectively connected to the second contact vias 790A. Subsequently, second bonding pads 770B may be formed. The second bonding pads 770B may be connected to at least one of the second lines 790B. The second contact vias 790A, the second lines 790B, and the second bonding pads 770B may be formed in the second interlayer insulating layer IL2.

Subsequently, the first semiconductor structure SS1 and the second semiconductor structure SS2 may be bonded. For example, an upper surface of the first semiconductor structure SS1 and an upper surface of the second semiconductor structure SS2 may be bonded. The first bonding pads 770A of the first semiconductor structure SS1 and the second bonding pads 770B of the second semiconductor structure SS2 may be bonded. The first semiconductor structure SS1 may be rotated and bonded to the second semiconductor structure SS2.

Referring to FIG. 7B, the substrate 1 exposed on a rear surface of the first semiconductor structure SS1 may be removed. When removing the substrate 1, the channel structures 740 may be exposed. Subsequently, a portion of the memory layer 740B of the channel structures 740 may be removed to expose the channel layer 740A. Subsequently, a source structure 710 may be formed on the gate structure 730G. Here, the source structure 710 may be connected to the channel layer 740A of the channel structures 740.

According to the manufacturing method described above, a memory cell array including the channel structures 740 and the like may be formed in the first semiconductor structure SS1. The second semiconductor structure SS2 may form the peripheral circuit PC or the like related to an operation of the memory cell array of the first semiconductor structure SS1. Therefore, by forming circuits related to the operation of the memory cell array in the separate second semiconductor structure SS2, more memory cells may be formed in the first semiconductor structure SS1, and thus more data may be stored.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a source structure;
a support structure disposed over the source structure, the support structure including a first inclined surface extending in a second direction crossing the first direction;
a gate structure disposed over the source structure and the support structure, the gate structure including conductive layers and insulating layers alternately stacked;
channel structures passing through the gate structure to connect to the source structure; and
a slit structure extending in the first direction through the gate structure,
wherein each of the conductive layers includes a second inclined surface extending in the second direction.

2. The semiconductor device of claim 1, wherein at least one of the channel structures extends through the second inclined surface.

3. The semiconductor device of claim 1, wherein each of the conductive layers has a wave-like shape in a cross-section.

4. The semiconductor device of claim 1, wherein the support structure includes supports spaced apart in the first direction, and wherein each support has a trapezoidal shape or a triangular shape.

5. The semiconductor device of claim 4, wherein the supports are adjacent in the second direction, and the slit structure is positioned between the supports adjacent in the second direction.

6. The semiconductor device of claim 1, wherein the first inclined surface includes a curved surface or an angled surface.

7. The semiconductor device of claim 1, wherein the support structure includes a material having an etch selectivity with respect to nitride.

8. The semiconductor device of claim 1, wherein the support structure includes an insulating material.

9. A semiconductor device comprising:
a support structure including a first inclined surface;
a gate structure including insulating layers and conductive layers alternately stacked on the support structure, each of the conductive layers including a second inclined surface;
a channel structure extending through the second inclined surface of the gate structure; and
a slit structure extending in a direction crossing the second inclined surface in the gate structure.

10. The semiconductor device of claim 9, wherein each of the conductive layers has a wave-like shape in a cross-section.

11. The semiconductor device of claim 9, wherein the first inclined surface includes a curved surface or an angled surface.

12. The semiconductor device of claim 9, wherein the support structure includes a material having an etch selectivity with respect to nitride.

13. The semiconductor device of claim 9, wherein the support structure includes an insulating material.

14. A semiconductor device comprising:
a source structure;
a support structure disposed over the source structure, the support structure including a plurality of supports arranged along a first direction;
a gate structure disposed over the support structure, the gate structure including conductive layers and insulating layers alternately stacked; and
channel structures passing through the gate structure to connect to the source structure,
wherein the support structure has an overall wave-like profile with a plurality of alternating convex protrusions and concave valleys; and
wherein each of the conductive layers includes a wave-like profile extending in the second direction.
